(19) United States
(12) Patent Application Publication
(10) Pub. No.: US 2003/0092290 A1
(43) Pub. Date: May 15, 2003

(54) Connection support fitted with a retaining collar

(76) Inventors: Herve Le Gallic, Cherreau (FR); Stephane Clavier, Champagne (FR); Rachel Chabirand, Champagne (FR); Pascal Ribeau, Le Mans (FR)

Correspondence Address: PERMAN & GREEN, 425 POST ROAD, FAIRFIELD, CT, 06824, US

(21) Appl. No.: 10/288,859

(22) Filed: Nov. 6, 2002

(30) Foreign Application Priority Data
Nov. 8, 2001 (FR) FR 01/14497

(51) Int. Cl. H05K 1/00

(52) U.S. Cl. 439/63

(57) ABSTRACT

Connection support comprising an insulator housing inside which a coaxial connector is provided. The coaxial connector comprises a plug-shaped load contact and a ground contact. The load contact is placed inside a cavity of the housing. The ground contact is on an inner rim of this cavity. The connection support comprises a retaining collar to cooperate with an outer rim of a matching connector that can be inserted into the cavity. This outer rim corresponds to the same rim with which the ground contact cooperates. This retaining collar preferably has the an open annular shape.

An object of the present invention is a connection support fitted with a retaining collar. It can be used more particularly in the field of coaxial connectors, especially connectors designed to receive coaxial sockets or female connectors. Indeed, there are known connection supports comprising a male connector or plug placed within a cavity of the support in such a way that the socket can be introduced into the cavity and in such a way that the plug is then inserted into a housing of the socket. Furthermore, these supports have a second contact made on an inner rim of the cavity of the support to co-operate with an outer rim of the socket. These connections are made by inserting one of the connector elements into the other. The value of the invention lies in the fact that it proposes a means to retain the matching slot when it is inserted into the connection support.

In the prior art, there is a connection support known from the teaching of the document FR-A-2,809,538. This connection support comprises a housing and a coaxial connector. The coaxial connector is presented in a cavity of the housing. The coaxial connector comprises, firstly, a load contact and, secondly, a ground contact. The load contact takes the form of a plug extending into the cavity so as to stand perpendicularly to an entry face of the cavity. Furthermore, the ground contact takes the form of an elastic contact strip extending beyond an inner rim of the cavity. Thus, the cavity may receive a matching coaxial connector in such a way that the plug can be inserted into a housing of the matching connector, while the elastic contact strip presses against an external rim, which is also conductive, of this matching connector. In this document, the solution implemented to form this ground contact is to propose a circular ground contact. In this case, the circular ground contact fulfils both a retaining function and a conduction function.

The problem raised by a connection support of this kind is that the ground contact which fulfils both a retaining function and a conduction function should be capable of ensuring high pressure of contact around the matching socket. This has the consequence of creating substantial friction on the conductive outer rim of the matching connector and hence of gradually damaging this rim and reducing its conductive capacities. The value of the invention precisely is that it dissociates the contact functions from the retaining functions. To this end, to dissociate the functions, the means used to perform each of these functions are dissociated. The connection support therefore comprises an additional retaining means. This retaining means is independent of the load and ground contacts.

Preferably, this retaining means takes the form of the collar. This collar is held in a same internal rim of the cavity as the rim beyond which the ground contact extends. However, these two elements, namely the collar and the ground contact, are positioned at different depths inside the cavity so as to effectively disassociate these two functions. Furthermore, the retaining function is fulfilled in the deepest part so as the length of the zone of the external rim that rubs against the collar. The advantage lies in the fact that this terminal part has no conductive function.

The invention relates to a connection support comprising an insulator housing and a coaxial connector, the coaxial connector comprising at least one load contact and one ground contact, the load contact extending in a cavity of the housing and the ground contact going beyond an inner rim of this cavity, characterised in that the connection support comprises a retaining collar positioned in a groove formed in the inner rim of the cavity, the collar being designed to retain a matching connector that can be inserted into the cavity of the support.

The invention will be understood more clearly from the following description and from the appended figures. These figures are given purely by way of an indication and in no way restrict the scope of the invention. Of these figures:

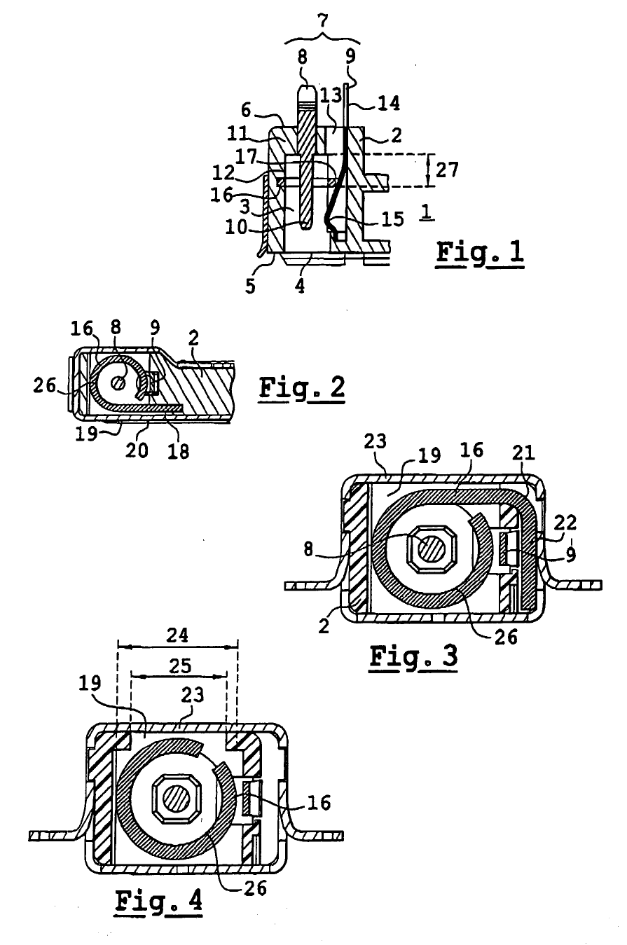

FIG. 1 is a longitudinal-section view of a connection support according to the invention;

FIG. 2 is a cross-section view of a first embodiment of the connection support according to the invention;

FIG. 3 is a cross-section view of a second embodiment of the connection support according to the invention

FIG. 4 is a cross-section view of a third embodiment of the connection support according to the invention.

FIG. 1 shows a connection support 1 according to the invention. This connection support 1 comprises an insulator housing 2. In this insulator housing 2, a cavity 3 is formed so that an aperture 4 of this cavity 3 opens on to a front face 5 of the insulator housing 2. The insulator housing 2 also has a rear face 6 opposite the front face 5. The sectional view shown in FIG. 1 is such that the section is made perpendicularly, and is made between the front face 5 and the rear face 6.

The connection support 1 also has a coaxial connector 7. This coaxial connector 7 comprises at least two contacts: a first contact called a load contact 8 and a second contact called a ground contact 9. The contacts 8 and 9 are both conductive and independent. In the embodiment shown in FIG. 1, the load contact 8 is, for example, a cylindrical plug extending into the cavity 3. Preferably, this cylindrical plug 8 is inserted from the rear face 6 so as to present a front end 10, which is also cylindrical, inside the cavity 3. This front end 10 is furthermore presented, also perpendicularly, into the aperture 4 of the front face 5. Thus, a matching connector, presented so as to face the aperture 4 and so as to be positioned perpendicularly to the front face 5, is designed so that it can be inserted into the cavity 3 and receive the front end 10 in one of its housings. The load contact 8 is retained at a back 11 on the rear face 6 side of the insulator housing 2.

Furthermore, the ground contact 9 in this example is an elastic metal strip curved in such a way that it is presented at an inner rim 12 of the cavity 3. Indeed, the cavity 3 has a groove 13 formed in this inner rim 12, in which the ground contact 9 is mounted. In this position, the contact 9 has a rear end 14 going beyond the rear face 6 side and being held thereon. It also has a flexible front portion 15 that is presented so that it goes beyond the inner rim 12. This front portion 15 has a flexibility defined in such a way that this strip can be shifted in parallel to the plane formed by the front face 5 and rear phase 6 and in these positions respectively so that it can go beyond the inner rim 12 or be pushed into the groove 13.

The connection support 1 has a retaining collar 16. This retaining collar 16 is preferably mounted inside the cavity 3. To this end, since the matching connector is designed to be inserted in the cavity 3, this collar 16 is presented at the inner rim 12. Indeed, the role of the collar 16 is to tighten an outer rim of the matching connector, while remaining lightly held in a second groove 17 of the inner rim 12. In this inner position, the retaining collar is retained by the second groove 17 and, at the same time, compressed against the outer rim of the matching connector. It therefore fulfils its retaining function.

Preferably, the retaining collar 16 is made out of a metallic material. The retaining collar 16 is preferably elastic. This elasticity may be conferred, for example, by the material out of which this collar 16 is made. However, in one embodiment, in which this collar 16 has an open toroidal shape, greater elasticity may be obtained for the collar 16 by means of its aperture and because of its possible play or travel. In this case, the collar 16 has an overall annular or ring shape. However, this ring will have an aperture that enables the enlargement, as a function of the presence or absence of a matching connector, of an internal diameter of this ring.

In one variant, the collar 16 takes the form of a U-shaped pin. It has two legs, elastically arched toward each other in such a way that the minimum distance between the two legs with smaller than the outer diameter of the outer rim of the matching connector. Thus, when it is connected to the support, the two legs get elastically stressed on the outer rim, possibly by co-operating with a recessed feature on this rim.

FIG. 2 shows a first embodiment of the collar 16. According to this first embodiment, the collar 16 has an open annular or ring shape and is provided with a holding lug 18. This holding lug 18 is used to retain the collar 16 in the housing 2. In a preferred embodiment, the housing preferably has a slot 19 on one face of the housing 2 inserted the collar 16 into the cavity 3 from the exterior of this housing 2. FIG. 2 corresponds to a section view parallel to the front and rear faces 5 and 6. The slot 19 is presented on an inner face 20 side of the insulator housing 2.

In the embodiment shown in FIG. 3, the collar 16 is also provided with a holding lug 18. This holding lug 18 is used to retain the collar 16 when it is subjected to elastic stresses, especially during connections and disconnections of the matching connector. And in this case, the holding lug 18 is elbowed and comprises an elbow 21 so that a front portion 22 of the holding lug 18 is presented perpendicularly to the slot 19. The presence of this elbow 21 also guarantees the position of the collar 16 inside the cavity 3. Indeed, the front lug 22 is preferably received in a matching housing in such a way that the position of the collar 16 in the cavity 3 is ensured. The collar here does not obstruct the central orifice. In this example, the housing 2 is covered with a casing 23 that obstructs the slot 19 when the connection support 1 is fully mounted.

In the alternative embodiments shown in FIGS. 3 and 4, in both cases, the slot 19 is covered by means of a casing 23 that ensures the closing of the casing and therefore ensures that the collar 16 is definitely held within the cavity 3.

In a third embodiment shown in FIG. 4, the collar 16 has no holding lug such as 18. In this case, the collar 16 corresponds to a simple open annulus. An outer diameter 24 of this ring is such that it is slightly greater than a width 25 of the slot 19. Thus, to insert the collar 16 into the housing 2, this collar 16 is stressed in such a way as to force its introduction from the slot 19. However, once it is inside the second groove 17, the retaining collar 16 elastically resumes its shape and then attains its stress-free external diameter 24 so as to prevent the exit of the collar 16 from the second groove 17 and hence from inside the housing 2.

In a preferred embodiment, an inner rim 26 of the retaining collar 16 is rounded or chamfered so that cooperation with an outer rim of the matching connector takes place without catching.

Preferably, the second groove 17 and hence the collar 16 are positioned in the cavity at a depth 27 determined from the back 11. For example, a depth 27 corresponds to a distance between the back 11 and the retaining collar 16. This distance 27 such that it corresponds approximately to a distance between a terminal end of the matching connector and a recess designed on the outer rim of this matching connector. In this case, the collar 16 may co-operate with the recess and thus ensure retention.

In a preferred embodiment, this connection support is mounted inside a mobile telephone. It is used for example to receive a matching connector of this support so that, for example, it fulfils power supply functions.

What is claimed is:

1. Connection support comprising an insulator housing and a coaxial connector, the coaxial connector comprising at least one load contact and one ground contact, the load contact extending in a cavity of the housing and the ground contact going beyond an inner rim of this cavity, characterised in that the connection support comprises a retaining collar positioned in a groove formed in the inner rim of the cavity, the collar being designed to retain a matching connector that can be inserted into the cavity of the support.

2. Connection support according to claim 1 characterised in that the housing has a slot on an outer rim enabling the introduction of the collar into the groove from this slot.

3. Connection support according to claim 1 characterised in that the collar is elastic.

4. Connection support according to claim 1 characterised in that the collar has an open toroidal shape, for example corresponding to an open ring.

5. Connection support according to claim 1 characterised in that the collar forms a U-shaped pin.

6. Connection support according to claim 1 characterised in that the collar comprises a holding lug to be held in the housing.

7. Connection support according to claim 1 characterised in that the collar is positioned in the cavity in such a way that it is designed to cooperate with a recess of the matching connector.

8. Connection support according to claim 1 characterised in that the load contact is plug-shaped and is inserted from a rear face into the housing.

9. Connection support according to claim 1 characterised in that it fulfils a power supply function within a mobile telephone in which it is mounted.
